(19) United States
(12) Patent Application Publication
(10) Pub. No.: US 2024/0258484 A1
(43) Pub. Date: Aug. 1, 2024

(54) Display Device and Method for Manufacturing the Same

(71) Applicant: LG DISPLAY CO, LTD., Seoul (KR)

(72) Inventors: Moonbae Gee, Paju-si (KR); Hyokang Lee, Seoul (KR)

(21) Appl. No.: 18/421,568

(22) Filed: Jan. 24, 2024

(30) Foreign Application Priority Data
Jan. 27, 2023 (KR) 10-2023-0011172

(51) Int. Cl. H01L 33/62; G09G 3/3225; H01L 25/16; H01L 27/12

(52) U.S. Cl. CPC H01L 33/62; G09G 3/3225; H01L 25/167; H01L 27/1248; G09G 2300/0842

(57) ABSTRACT

Disclosed is a display device in which a redundant light-emitting element is applicable to a micro light-emitting display device to which a high-resolution panel is applied. The display device includes at least one light-emitting element; and at least one redundant light-emitting element respectively disposed in a manner corresponding to the at least one light-emitting element, wherein a first electrode of the light-emitting element is connected to a second electrode of the redundant light-emitting element via a connection electrode. Thus, even when the light-emitting element is defective, light of a corresponding color thereto is emitted normally from the redundant light-emitting element. Thus, a failure of each pixel may be lowered.

### CROSS-REFERENCE TO RELATED APPLICATION

This application claims priority from Republic of Korea Patent Application No. 10-2023-0011172 filed on Jan. 27, 2023 in the Korean Intellectual Property Office, and all the benefits accruing therefrom under 35 U.S.C. 119, which is hereby incorporated by reference in its entirety.

### BACKGROUND

### Field

The present disclosure relates to a display device and a method for manufacturing the same.

### Description of Related Art

A display device with its own light-emitting element may be implemented to be thinner than a display device with a built-in light source, and may be able to implement a flexible and foldable display device.

Such a display device having its own light-emitting element may be classified into an organic light-emitting display device including a light-emitting layer made of an organic material and a micro-LED display device using a micro-LED element as a light-emitting element.

The organic light-emitting display device using the organic material does not require a separate light source. However, in the organic light-emitting display device, a defective pixel due to moisture and oxygen may easily occur. Thus, various technical ideas are additionally required to minimize penetration of oxygen and moisture. In response to this requirement, recently, research and development on a micro light-emitting display device using a micro light-emitting diode as a light-emitting element has been conducted.

### SUMMARY

However, in the micro light-emitting display device, when a light-emitting element is used in a flip chip or lateral chip scheme, an area required for transfer thereof is large, thus making it difficult to apply a redundant light-emitting element to a high-resolution panel.

Therefore, it is difficult to apply the redundant light-emitting element to the high-resolution panel in the micro light-emitting display device. Thus, a large number of defective pixels may occur.

Accordingly, in order to solve the above-mentioned problem, the inventors of the present disclosure have invented a display device in which a redundant light-emitting element can be applied to a micro light-emitting display device to which a high-resolution panel is applied.

Therefore, a purpose of the present disclosure is to provide a display device in which a redundant light-emitting element is disposed in a manner corresponding to a main light-emitting element, and the main light-emitting element and the redundant light-emitting element are connected to each other via a connection electrode such that electrodes having opposite polarities of the main light-emitting element and the redundant light-emitting element are connected to each other. Further, a purpose of the present disclosure is to provide a method for manufacturing the display device.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In one embodiment, a display device comprising: a light-emitting element including a first electrode of a first type, a second electrode of a second type that is different from the first type and disposed opposite the first electrode, and a first light emitting layer between the first electrode of the first type and the second electrode of the second type; a redundant light-emitting element including a second electrode of the second type, a first electrode of the first type that is disposed opposite the second electrode of the second type of the redundant light-emitting element, and a second light emitting layer between the second electrode of the second type and the first electrode of the first type of the redundant light-emitting element; and a connection electrode connected to the first electrode of the first type of the light-emitting element and the second electrode of the second type of the redundant light-emitting element.

In one embodiment, a method for manufacturing a display device including a thin-film transistor layer comprises: disposing an anode electrode and a cathode electrode on a first planarization layer that is on the thin-film transistor layer; disposing a first N-type electrode on the anode electrode and a second P-type electrode on the cathode electrode; disposing a first light-emitting layer on the first N-type electrode and a second light-emitting layer on the second P-type electrode; disposing a first P-type electrode on the first light-emitting layer to form a redundant light-emitting element and a second N-type electrode on the second light-emitting layer to form a redundant light-emitting element; disposing a second planarization layer on the first planarization layer, the second planarization layer between the first P-type electrode and the second N-type electrode; and disposing a connection electrode on the second planarization layer, the connection electrode connected to the first P-type electrode and the second N-type electrode.

In one embodiment, a display device comprises: a planarization layer having a first side and a second side that is opposite the first side; a first P-type electrode at the first side of the planarization layer; a first N-type electrode at the first side of the planarization layer; a first light emitting layer between the first P-type electrode and the first N-type electrode at the first side of the planarization layer; a second N-type electrode at the second side of the planarization layer; a second P-type electrode at the second side of the planarization layer; a second light emitting layer between the second N-type electrode and the second P-type electrode; and a connection electrode including a first end that is connected to the first P-type electrode at the first side of the planarization layer and a second end that is connected to the second N-type electrode at the second side of the planarization layer.

According to the embodiments of the present disclosure, a high-resolution display panel may be applied to a micro light-emitting display device.

Further, according to the embodiments of the present disclosure, the failure of each pixel may be lowered because the redundant light-emitting element corresponding to each main light-emitting element is disposed.

Further, according to the embodiments of the present disclosure, even when one light-emitting element is defective in the micro light-emitting display device, light of a corresponding color thereto may be emitted from the redundant light-emitting element corresponding thereto, thereby reducing a repair cost.

Further, according to the embodiment of the present disclosure, a pixel defect may be reduced due to the presence of the redundant light-emitting element corresponding to each main light-emitting element. Thus, a lifespan of the micro light-emitting display device may be improved, and thus a long lifespan display device may be realized.

Further, according to the embodiments of the present disclosure, high quality and high reliability of a display device may be achieved by reducing the pixel defect.

Further, according to the embodiments of the present disclosure, as the micro light-emitting element has a vertical structure, a size of the chip may be reduced, thereby reducing the chip cost of the micro light-emitting display device.

Furthermore, according to the embodiments of the present disclosure, a high-resolution display device using a micro light-emitting element and a method for manufacturing the same may be provided.

In addition to the above effects, specific effects of the present disclosure are described together while describing specific details for carrying out the present disclosure.

Effects of the present disclosure are not limited to the effects mentioned above, and other effects not mentioned will be clearly understood by those skilled in the art from the descriptions below.

### BRIEF DESCRIPTION OF DRAWINGS

FIG. 1 is a schematic plan view illustrating a display device having a plurality of sub-pixels according to one embodiment of the present disclosure.

FIG. 2 is a schematic circuit diagram illustrating a driver circuit for driving a sub-pixel according to one embodiment of the present disclosure.

FIG. 3 is a schematic cross-sectional view along a cutting line 3 of FIG. 1 to illustrate a sub-pixel in which a light-emitting element according to one embodiment of the present disclosure is used.

FIG. 4 is a plan view schematically illustrating a display device according to one embodiment of the present disclosure.

FIG. 5 is a diagram showing a structure in which a main light-emitting element and a redundant light-emitting element are connected to each other via a connection electrode according to one embodiment of the present disclosure.

FIGS. 6 and 7 are cross-sectional views of a display device taken along a cutting line 6-6 of FIG. 5 according to one embodiment of the present disclosure.

FIG. 8 is a flowchart illustrating a method for manufacturing a display device according to one embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element or layer may be disposed directly on the second element or layer or may be disposed indirectly on the second element or layer with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device and a method for manufacturing the display device according to an embodiment of the present disclosure will be described.

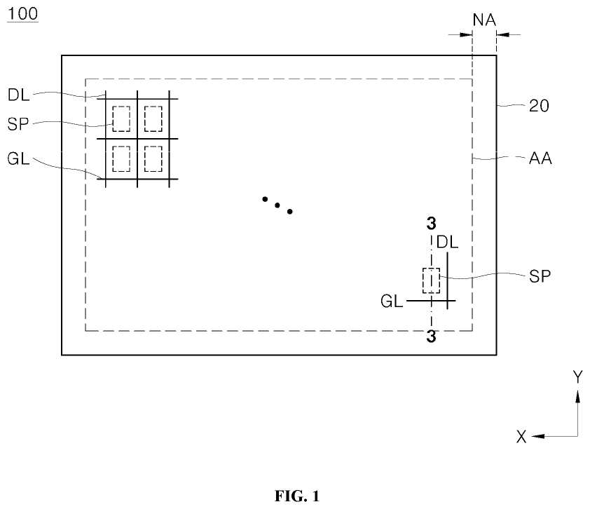

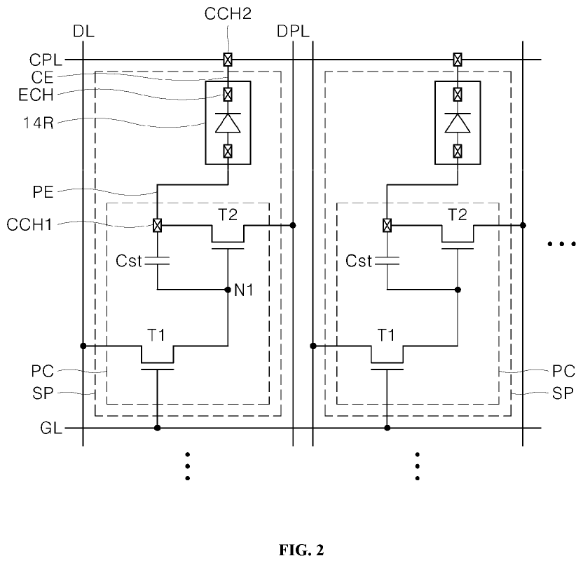

FIG. 1 is a schematic plan view illustrating a display device having a plurality of sub-pixels according to one embodiment of the present disclosure. FIG. 2 is a schematic circuit diagram illustrating a driver circuit for driving a sub-pixel according to one embodiment of the present disclosure.

With reference to FIG. 1 and FIG. 2, a display device 100 according to one embodiment of the present disclosure may include a substrate 20 having a display area AA on which a plurality of sub-pixels SP are disposed, and a non-display area NA disposed to surround the display area.

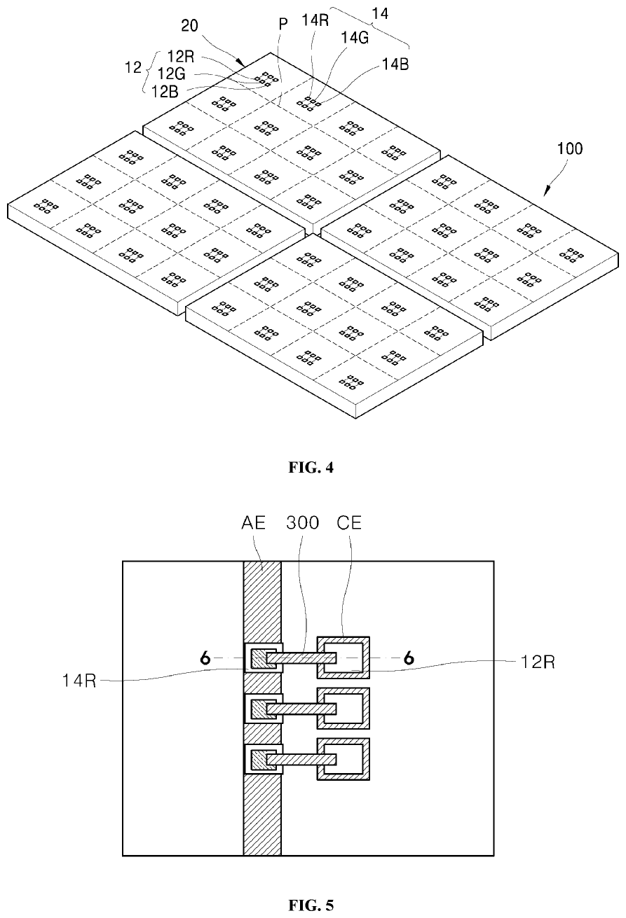

The sub-pixels SP disposed on the display area AA of the substrate 20 may include sub-pixels SP that emit red, blue, and green lights, respectively. However, the present disclosure is not limited thereto. Alternatively, the sub-pixels SP may further include a sub-pixel that emits white light. In this regard, the sub-pixel may be referred to as “a light-emitting element 14”. The light-emitting element 14 may be embodied as, for example, a micro light-emitting diode element 14 (see FIG. 4) or a micro-LED chip 14. The micro light-emitting diode element 14 may be labeled as “a micro-LED element 14”, and the micro-LED chip 14 may be labeled as “a micro-LED chip 14”.

The substrate 20 may be embodied as a thin-film transistor array substrate, and may be made of glass or plastic material. The substrate may be formed by bonding two or more substrates to each other, or may be divided into two or more layers. The non-display area NA may be defined as a partial area of the substrate 20 excluding the display area AA, and may have a relatively smaller width, and may be defined as a bezel area.

In this regard, on the display area AA of the substrate 20, a large number of light-emitting elements 14 as the sub-pixels may be arranged to constitute a display panel. Thus, hereinafter, the substrate 20 may be referred to as “a display panel 20”.

Further, the display device 100 includes the substrate 20 on which the plurality of light-emitting elements 14 are disposed. Hereinafter, for example, the display device 100 may be referred to as “a light-emitting display device 100” or “a micro light-emitting display device 100”.

In the display device 100 including the light-emitting element 14, a width of the non-display area NA may be smaller than a pixel pitch or a sub-pixel pitch. When a multi-screen display device is implemented with the display device 100 in which the width of the non-display area NA is smaller than the pixel pitch or the sub-pixel pitch, a multi-screen display device with substantially no bezel area may be realized because the width of the non-display area NA is smaller than the pixel pitch or sub-pixel pitch.

In the display device 100 with different pixel pitches, a distortion phenomenon of the image may occur. Thus, not only may the distortion phenomenon of the image be reduced but the bezel area may also be reduced by performing image processing in a manner of sampling image data based on comparison between adjacent areas in consideration of a set pixel pitch.

Referring to FIG. 2, a configuration and a circuit structure of the sub-pixel SP constituting a unit pixel of the display device 100 will be described. Pixel driving lines may extend across an entire surface of the substrate 20 and may supply signals to each of a plurality of sub-pixels SP. The pixel driving lines according to one embodiment of the present disclosure may include a plurality of gate lines GL, a plurality of data lines DL, a plurality of driving power lines DPL, and a plurality of common power lines CPL.

Each of the plurality of gate lines GLs may extend across the entire surface of the substrate 20 and may extend in an elongate manner along a first horizontal axis direction (for example, an X axis direction) of the substrate 20. The plurality of gate lines GL may be arranged so as to be spaced from each other by an equal spacing along a second horizontal axis direction (for example, a Y axis direction).

Each of the plurality of data lines DL may extend across the entire surface of the substrate 20 and may extend so as to intersect the plurality of gate lines GL, and thus may extend in an elongate manner along the second horizontal axis direction (for example, the Y axis direction). The plurality of data lines DL may be arranged so as to be spaced from each other by an equal spacing along the first horizontal axis direction (for example, the X axis direction).

Each of the plurality of driving power lines DPLs may extend across the entire surface of the substrate 20 and may extend so as to intersect the plurality of gate lines GL, and thus may extend in an elongate manner along the second horizontal axis direction (for example, the Y axis direction). The plurality of driving power lines DPLs may be arranged so as to be spaced from each other by an equal spacing along the first horizontal axis direction (for example, the X axis direction). Each of the plurality of driving power lines DPL may be spaced apart from each of the plurality of data lines DL and may extend in parallel with each of the plurality of data lines DL. Each of the plurality of driving power lines DPL supplies a driving power supplied from an external source to a sub-pixel SP adjacent thereto.

Each of the plurality of common power lines CPL may extend across the entire surface of the substrate 20 and may extend in an elongate manner along the first horizontal axis direction (for example, the X axis direction) of the substrate 20. The plurality of common power lines CPL may be arranged so as to be spaced apart from each other by an equal spacing along the second horizontal axis direction (for example, the Y axis direction). Each of the plurality of common power lines CPL may be spaced from each of the plurality of gate lines GL and may extend in parallel with each of the plurality of gate lines GL. Each of the plurality of common power lines CPL supplies a common power provided from an external source to a sub-pixel SP adjacent thereto.

Each of the plurality of sub-pixels SP is disposed in each of sub-pixel areas at each of intersections of the gate lines GL and the data lines DL. Each of the plurality of sub-pixels SP may be defined as a minimum unit area in which light is actually emitted.

At least three sub-pixels SP adjacent to each other may constitute one unit pixel for color display. For example, one unit pixel may include sub-pixels SP respectively emitting red (R), green (G), and blue (B) lights and adjacent to each other along the first horizontal axis direction (the X axis direction). Alternatively, one unit pixel may further include a sub-pixel SP emitting a white (W) light to improve luminance.

Optionally, one driving power lines DPL may be provided in each of a plurality of unit pixels. In this case, the at least three sub-pixels SP constituting one unit pixel may share one driving power line DPL. Accordingly, the number of driving power lines for operating the sub-pixels SP may be reduced, and an aperture ratio of each unit pixel may be increased, or a size of each unit pixel may be reduced as much as the number of reduced driving power lines.

Each of the plurality of sub-pixels SP according to one embodiment of the present disclosure includes a driver circuit PC and a light-emitting element 14R.

The driver circuit PC is disposed in a circuit area defined in each sub-pixel SP and is connected to the gate line GL, the data line DL, and the driving power line DPL adjacent thereto. Based on the driving power supplied thereto from the driving power line DPL, the driver circuit PC may control the current flowing in the light-emitting element 14R according to a data signal from the data line DL and in response to a scan pulse from the gate line GL. The driver circuit PC according to one embodiment of the present disclosure includes a switching transistor T1, a driving transistor T2, and a capacitor Cst.

The switching transistor T1 includes a gate electrode connected to the gate line GL, a first electrode connected to the data line DL, and a second electrode connected to a gate electrode of the driving transistor T2 at node N1. In this regard, the first and second electrodes of the switching transistor T1 may be respectively a source electrode and a drain electrode, or a drain electrode and a source electrode based on a direction of the current. This switching transistor T1 may be switched according to the scan pulse supplied to the gate line GL to supply the data signal supplied to the data line DL to the driving transistor T2.

The driving transistor T2 may be turned on based on the voltage supplied from the switching transistor T1 and/or a voltage of the capacitor Cst to control an amount of the current flowing from the driving power line DPL to the light-emitting element 14R. To this end, the driving transistor T2 according to one embodiment of the present disclosure includes a gate electrode N1 connected to the second electrode of the switching transistor T1 at node N1, a drain electrode connected to the driving power line DPL, and a source electrode connected to the light-emitting element 14R. The driving transistor T2 may control the data current flowing from the driving power line DPL to the light-emitting element 14R based on the data signal supplied from the switching transistor T1 to control light emission of the light-emitting element 14R.

The capacitor Cst is disposed so as to overlap an area between the gate electrode and the source electrode of the driving transistor T2 and stores therein a voltage corresponding to the data signal supplied to the gate electrode of driving transistor T2, and turns on the driving transistor T2 with the stored voltage.

Optionally, the driver circuit PC may further include at least one compensation transistor for compensating for change in a threshold voltage of the driving transistor T2. Furthermore, the driver circuit PC may further include at least one auxiliary capacitor. This driver circuit PC may additionally receive a compensation power such as an initialization voltage, depending on the number of transistors and auxiliary capacitors. Therefore, the driver circuit PC according to one embodiment of the present disclosure drives the light-emitting element 14R in a current driving manner as that in which each of a pixel circuit of the sub-pixels SP of the display device does. Thus, the driver circuit PC according to one embodiment of the present disclosure may act as a known pixel circuit of the organic light-emitting display device.

The light-emitting element 14R is disposed in each of the plurality of sub-pixels SP. This light-emitting element 14R is electrically connected to the driver circuit PC of the corresponding sub-pixel SP and the common power line CPL and thus emits light based on the current flowing from the driver circuit PC, that is, the driving transistor T2 thereof to the common power line CPL. The light-emitting element 14R according to one embodiment of the present disclosure may be embodied as a light-emitting element or a light-emitting diode chip that emits one of red light, green light, blue light, and white light. In this regard, the light-emitting diode chip may have a scale of 1 micrometers to 100 micrometers (μm). However, the present disclosure is not limited thereto. The light-emitting diode chip may have a smaller size than a size of the light-emitting area other than the circuit area occupied by the driver circuit PC in an area of the sub-pixel SP.

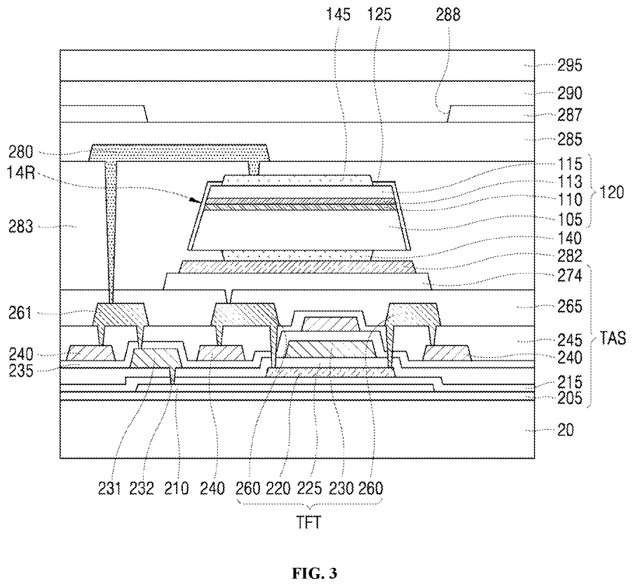

FIG. 3 is a schematic cross-sectional view along a cutting line 3 of FIG. 1 to illustrate a sub-pixel in which a light-emitting element according to one embodiment of the present disclosure is used.

FIG. 3 shows a cross-sectional structure of one sub-pixel SP of the display device 100 according to one embodiment of the present disclosure. Hereinafter, the present disclosure will be described with reference to FIG. 2 and FIG. 3, while being described in connection with the previous drawings.

The display device 100 according to one embodiment of the present disclosure includes the light-emitting element 14R mounted on a thin-film transistor layer TAS. The light-emitting element 14R may be mounted on the thin-film transistor layer TAS in a transfer process.

An example in which the light-emitting element 14R belongs to a sub-pixel SP emitting red (R) light is described. However, the present disclosure is not limited thereto. The following descriptions may be applied to a light-emitting element 14G which belongs to a sub-pixel SP emitting green (G) light, and a light-emitting element 14B which belongs to a sub-pixel SP emitting blue (B) light.

The thin-film transistor layer TAS may include a pixel driver circuit configured to drive the light-emitting element 14R. For example, the thin-film transistor layer TAS may include a thin-film transistor TFT, a line and an electrode disposed on the substrate 20.

The thin-film transistor TFT may include a semiconductor layer 220 formed on the substrate 20, a gate electrode 230 positioned on the semiconductor layer 220, a gate insulating layer 225 disposed between the semiconductor layer 220 and the gate electrode 230, and source/drain electrodes 260.

A buffer layer 205 and a light-blocking layer 210 may be disposed between the substrate 20 and the semiconductor layer 220. However, the present disclosure is not limited thereto. Here, the light-blocking layer 210 may be referred to as “a light shield layer (LS)”.

The buffer layer 205 may prevent or at least reduce impurities or moisture from diffusing from the substrate 20 toward the thin-film transistor TFT, and may include an inorganic insulating material. In one example, the buffer layer 205 may include silicon nitride or silicon oxide. The buffer layer 205 may be formed as a single layer or multiple layers.

When the semiconductor layer 220 includes, for example, a metal oxide semiconductor, The light-blocking layer 210 serves to prevent or at least reduce light from entering the semiconductor layer 220. In one embodiment, a size of the light-blocking layer 210 is larger than that of the semiconductor layer 220 so as to entirely cover the semiconductor layer 220. The light-blocking layer 210 may be embodied as a single layer or a stack of multiple layers including at least one of titanium (Ti), molybdenum (Mo), copper (Cu), aluminum (Al), silver (Ag), chromium (Cr), gold (Au), neodymium (Nd), and nickel (Ni).

A first interlayer insulating layer 215 may be disposed between the buffer layer 205, the light-blocking layer 210, and the semiconductor layer 220.

The gate electrode 230 may be disposed on the gate insulating layer 225 so as to overlap the semiconductor layer 220. A first interlayer connection electrode 231 spaced apart from the gate electrode 230 may be disposed on the gate insulating layer 225. The first interlayer connection electrode 231 may be connected to the light-blocking layer 210 via a first interlayer connection portion 232 extending through the gate insulating layer 225 and the first interlayer insulating layer 215.

A second interlayer insulating layer 235 and a third interlayer insulating layer 245 may be sequentially disposed on the gate electrode 230 and the first interlayer connection electrode 231.

A plurality of connection lines 240 disposed on the second interlayer insulating layer 235 may be covered with the third interlayer insulating layer 245. The source/drain electrodes 260 and a second interlayer connection electrode 261 may be disposed on the third interlayer insulating layer 245.

One side of each of the source/drain electrodes 260 may extend through the third interlayer insulating layer 245, the second interlayer insulating layer 235, and the gate insulating layer 225 so as to be connected to the semiconductor layer 220. Then, the other side of each of the source/drain electrodes 260 may extend through the third interlayer insulating layer 245 so as to be connected to the connection line 240.

One side of the second interlayer connection electrode 261 may extend through the third interlayer insulating layer 245 and the second interlayer insulating layer 235 so as to be connected to the first interlayer connection electrode 231. The other side of the second interlayer connection electrode 261 may extend through the third interlayer insulating layer 245 so as to be connected to another connection line 240.

A first planarization layer 265 is disposed on the third interlayer insulating layer 245. The first planarization layer 265 may cover the second interlayer connection electrode 261 and the source/drain electrodes 260 of the thin-film transistor TFT.

On the first planarization layer 265, a first connection electrode 274 is disposed. The first connection electrode 274 may extend through the first planarization layer 265 so as to be electrically connected to one of the source/drain electrodes 260 of the thin-film transistor TFT. The first connection electrode 274 may be an anode electrode.

A conductive adhesive layer 282 is disposed on the first connection electrode 274. The conductive adhesive layer 282 may act as a layer for fixing the light-emitting element 14R to the first connection electrode 274 and may include a conductive material having adhesiveness.

The light-emitting element 14R is disposed on the conductive adhesive layer 282.

A side surface of the light-emitting element 14R may be surrounded with a second planarization layer 283. The second planarization layer 283 may cover an upper surface of the light-emitting element 14R. The second planarization layer 283 may cover a side surface of each of the first connection electrode 274 and the conductive adhesive layer 282. The second planarization layer 283 may include, for example, a photoactive organic material.

A second connection electrode 280 is disposed on the second planarization layer 283. One side of the second connection electrode 280 may extend through the second planarization layer 283 so as to be connected to a second light-emitting electrode 145 of the light-emitting element 14R. The other side of the second connection electrode 280 may extend through the second planarization layer 283 and the first planarization layer 265 so as to be connected to the second interlayer connection electrode 261. The second connection electrode 280 may be a cathode electrode.

The second interlayer connection electrode 261 may be connected to the light-blocking layer 210 via the first interlayer connection electrode 231. A second insulating layer 285 may be disposed on the second planarization layer 283 and the second connection electrode 280. The insulating layer 285 may include, for example, a photoactive organic material.

A bank 287 having a bank hole 288 defined therein may be disposed on the second insulating layer 285. The bank 287 may include a black matrix, in one example. Embodiments of the present disclosure are not limited thereto. A third planarization layer 290 is disposed on the bank 287. The third planarization layer 290 may cover a step caused by the bank 287 and the bank hole 288 so as to provide a flat top surface. In one example, the third planarization layer 290 may include, for example, a photoactive organic material.

A cover layer 295 may be disposed on the third planarization layer 290. The cover layer 295 may include a functional optical film such as an anti-scattering film.

The light-emitting element 14R according to the present disclosure may include a light-emitting structure (i.e., a light-emitting layer) 120, a passivation layer 125, a first light-emitting electrode 140, and the second light-emitting electrode 145. The light-emitting element 14R may have a vertical structure. A maximum width in the horizontal direction of the light-emitting element 14R may be, for example, 100 μm or smaller. The light-emitting element 14R may be referred to as a micro light-emitting diode (uLED).

The light-emitting structure 120 may include a first semiconductor layer 105, an active layer 110, an electron blocking layer 113, and a second semiconductor layer 115. In one example, the light-emitting structure 120 may have a shape in which a width thereof gradually decreases (e.g., tapers) as the light-emitting structure 120 extends from the first semiconductor layer 105 to the second semiconductor layer 115. In this case, a side surface of the light-emitting structure 120 may have an inclination.

The side surface of the light-emitting structure 120 may be covered with the passivation layer 125. The passivation layer 125 may extend to an upper surface of the second semiconductor layer 115 and may cover a portion of the upper surface of the second semiconductor layer 115. The passivation layer 125 may be made of, for example, an inorganic insulating material such as silicon oxide, silicon nitride, silicon oxynitride, or aluminum oxide.

The first light-emitting electrode 140 is connected to the first semiconductor layer 105, and the second light-emitting electrode 145 is connected to the second semiconductor layer 115. Since the light-emitting element 14R has the vertical structure, the first light-emitting electrode 140 may be referred to as a lower electrode, while the second light-emitting electrode 145 may be referred to as an upper electrode. When the first semiconductor layer 105 is an N-type semiconductor layer and the second semiconductor layer 115 is a P-type semiconductor layer, the first light-emitting electrode 140 may be referred to as an N-type electrode and the second light-emitting electrode 145 may be referred to as a P-type electrode.

The light-emitting structure 120 may be made of, for example, a group III nitride semiconductor material. However, the present disclosure is not limited thereto.

Each of the first semiconductor layer 105, the active layer 110, the electron blocking layer 113 and the second semiconductor layer 115 of the light-emitting structure 120 may be made of a group III nitride semiconductor material, that is, InₓAl_{y}Ga_{(1-x-y)}N(0≤x<1, 0≤y<1).

The first semiconductor layer 105 may act as a layer for supplying electrons to the active layer 110 and may be made of an n-type group III nitride semiconductor material doped with impurities such as silicon (Si), germanium (Ge), selenium (Se), and tellurium (Te). An energy bandgap of the first semiconductor layer 105 may decrease as the first semiconductor layer 105 extends away from the active layer 110. The energy band gap of the first semiconductor layer 105 may decrease as the first semiconductor layer 105 extends toward the first light-emitting electrode 140.

For example, the first semiconductor layer 105 may be made of an n-type indium gallium nitride (InGaN), that is, a n-type InₓGa₍₁₋ₓ₎N(0≤x<1). A content of indium (In) in the first semiconductor layer 105 may increase as the first semiconductor layer 105 extends away from the active layer 110.

The energy bandgap of the first semiconductor layer 105 may decrease linearly or gradually as the first semiconductor layer 105 extends away from the active layer 110. The content of indium (In) in the first semiconductor layer 105 may increase linearly or gradually as the first semiconductor layer 105 extends away from the active layer 110. The content of indium (In) may be the highest and the energy band gap may be the smallest at a lower surface of the first semiconductor layer 105 that contacts the first light-emitting electrode 140.

Accordingly, a potential barrier between the first light-emitting electrode 140 and the first semiconductor layer 105 may be lowered. As a result, a driving voltage and a driving current required for electrons to overcome the potential barrier between the first light-emitting electrode 140 and the first semiconductor layer 105 to be injected into the first semiconductor layer 105 may be lowered. Thus, the light-emitting element 14R may operate at a low current level.

The active layer 110 disposed on the first semiconductor layer 105 may have a Multi Quantum Well (MQW) structure. The active layer 110 may emit light based on recombination of electrons and holes. The multi-quantum well structure of the active layer 110 may include a plurality of barrier layers and a plurality of well layers. For example, the plurality of well layers may be made of indium gallium nitride (InGaN) and the plurality of barrier layers may be made of gallium nitride (GaN). A content of indium (In) in the well layer may be designed based on a wavelength of emitted light. The multi-quantum well structure of the active layer 110 is not limited to the above example.

The electron blocking layer 113 disposed on the active layer 110 may prevent electrons injected from the first semiconductor layer 105 into the active layer 110 from overflowing into the second semiconductor layer 115, and may be made of a p-type group III nitride semiconductor material doped with impurities such as magnesium (Mg), zinc (Zn), and beryllium (Be). The electron blocking layer 113 may include, for example, a p-type aluminum gallium nitride (AlGaN), that is, p-type Al_{y}Ga_{(1-y)}N(0≤y<1). In one embodiment, the electron blocking layer 113 may be omitted.

The second semiconductor layer 115 disposed on the electron blocking layer 113 may act as a layer for injecting holes into the active layer 110 and may be made of a p-type group III nitride semiconductor material doped with impurities such as magnesium (Mg), zinc (Zn), and beryllium (Be). The second semiconductor layer 115 may include, for example, p-type gallium nitride (GaN).

The first light-emitting electrode 140 is disposed on the lower surface of the first semiconductor layer 105, and may be composed of a single layer or a plurality of layers made of at least one of nickel (Ni), gold (Au), platinum (Pt), titanium (Ti), aluminum (Al), chromium (Cr), copper (Cu), or an alloy thereof.

As described above, the energy band gap of the first semiconductor layer 105 may gradually decrease as the first semiconductor layer 105 extends away from the active layer 110. The lower surface of the first semiconductor layer 105 in contact with the first light-emitting electrode 140 may have the smallest energy band gap.

Accordingly, the potential barrier between the first light-emitting electrode 140 and the first semiconductor layer 105 may be lowered. As a result, the driving voltage and the driving current required for electrons to overcome the potential barrier between the first light-emitting electrode 140 and the first semiconductor layer 105 so as to be injected into the first semiconductor layer 105 may be lowered. Thus, the light-emitting element 14R may operate in a low current range.

The second light-emitting electrode 145 disposed on an upper surface of the second semiconductor layer 115 may be composed of a single layer or a plurality of layers made of at least one of nickel (Ni), gold (Au), platinum (Pt), titanium (Ti), aluminum (Al), chromium (Cr), copper (Cu), or an alloy thereof.

An ohmic contact layer may be further disposed between the second semiconductor layer 115 and the second light-emitting electrode 145. The ohmic contact layer may include a transparent conductive oxide such as ITO (Indium Tin Oxide), IGZO (Indium Gallium Zinc Oxide), or IZO (Indium Zinc Oxide).

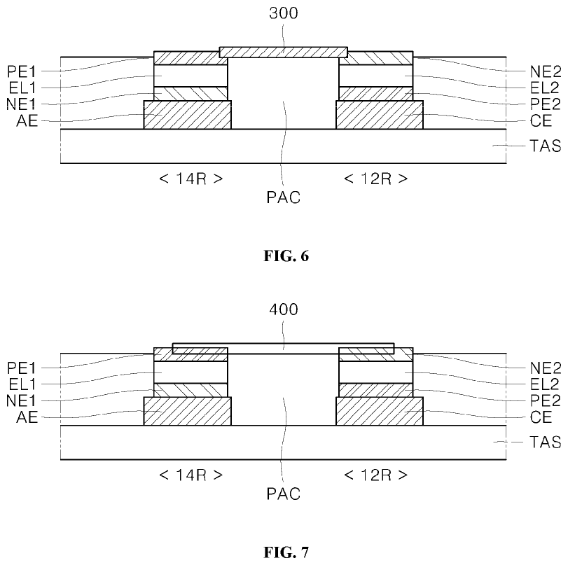

FIG. 4 is a plan view schematically illustrating a display device according to one embodiment of the present disclosure. FIG. 5 is a diagram showing a structure in which a main light-emitting element and a redundant light-emitting element are connected to each other via a connection electrode according to one embodiment of the present disclosure. FIGS. 6 and 7 are cross-sectional views of a display device taken along a cutting line 6 of FIG. 5 according to one embodiment of the present disclosure.

Referring to FIG. 4 to FIG. 7, the display device 100 according to one embodiment of the present disclosure may include the display panel 20 in which at least one light-emitting element 14R, 14G, and 14B are disposed.

The display panel 20 may include at least one redundant light-emitting element 12R, 12G, and 12B respectively disposed in a manner corresponding to the at least one light-emitting element.

A first electrode PE1 of the light-emitting element 14R may be connected to a second electrode NE2 of the redundant light-emitting element 12R via a connection electrode 300.

The light-emitting elements 14R, 14G, and 14B may belong to a first sub-pixel, a second sub-pixel, and a third sub-pixel, respectively. The first sub-pixel to the third sub-pixel may be configured to emit light beams of different colors. For example, the first sub-pixel may emit red (R) light, the second sub-pixel may emit green (G) light, and the third sub-pixel may emit blue (B) light.

The first sub-pixel, the second sub-pixel, and the third sub-pixel may include micro-LED elements 14R, 14G, and 14B, respectively. The micro-LED element 14 may be referred to as ‘a micro-LED chip 14’. Therefore, each of the first sub-pixel to the third sub-pixel may include the micro-LED element 14 or the micro-LED chip 14.

Further, each of the first sub-pixel to the third sub-pixel may include an organic light-emitting diode OLED.

The redundant light-emitting elements 12R, 12G, and 12B may belong to at the first sub-pixel, the second sub-pixel, and the third sub-pixel, respectively. The first sub-pixel to the third sub-pixel may be configured to emit light of different colors. For example, the first sub-pixel may emit red (R) light, the second sub-pixel may emit green (G) light, and the third sub-pixel may emit blue (B) light. That is, the light-emitting element and the redundant light-emitting element corresponding thereto belong to the same sub-pixel and emit light of same color.

In the display device 100 according to one embodiment of the present disclosure, each of a plurality of light-emitting elements 14 and each of a plurality of redundant light-emitting elements 12 mounted on the substrate 20 may be connected to each other via each connection electrode 300.

The substrate 20 may be made of a transparent material such as glass, and a plurality of pixel areas P are defined thereon. Although not shown in the drawing, the substrate 20 may be embodied as a TFT array substrate. A thin-film transistor for operating the light-emitting element 14 and various lines are formed on a pixel area P of an upper surface of the TFT array substrate. When the thin-film transistor is turned on, a driving signal input from an external source via the line is applied to the light-emitting element 14 so that the light-emitting element 14 emits light to display an image.

In this regard, the three light-emitting elements 14R, 14G, and 14B emitting monochromatic color lights R, G, and B, respectively, are mounted on each pixel area P of the substrate 20. Thus, when a signal is applied from an external source thereto, R, G, and B color lights may be respectively emitted from the light-emitting elements 14R, 14G, and 14B. In this way, an image may be displayed.

The light-emitting elements 14R, 14G, and 14B are manufactured in a process separate from a TFT array process of the substrate 20. In a general organic light-emitting display device, the TFT array and the organic light-emitting layer are formed in the same photo process. However, in the display device 100 of the present disclosure, the thin-film transistor and various lines disposed on the substrate 20 are formed in a photo process, while the light-emitting elements 14R, 14G, and 14B are manufactured in a separate process therefrom. Then, the separately manufactured light-emitting elements 14R, 14G, and 14B may be transferred onto the substrate 20. Thus, the display device is manufactured.

The light-emitting element 14 may be embodied as a 10 μm to 100 μm sized LED. The light-emitting element 14 may be formed by growing a plurality of thin-films made of an inorganic material such as Al, Ga, N, P, As, etc. on a sapphire substrate or a silicon substrate, and cutting the sapphire substrate or the silicon substrate and removing the sapphire substrate or the silicon substrate from the thin-films. In this way, the light-emitting element 14 may be formed in a micro size, and may be transferred to a flexible substrate made of plastic, making it possible to manufacture a flexible display device. Further, the light-emitting element 14 may be formed by growing the thin-film made of the inorganic material, unlike the organic light-emissive layer. Thus, the manufacturing process thereof is simplified, and a yield is improved. Moreover, the individually separated light-emitting elements 14 are simply transferred onto the large-area substrate 20, such that a large-area display device may be manufactured. Moreover, the light-emitting element 14 made of the inorganic material has advantages of high luminance, a long lifespan, and a low cost compared to the LED made of the organic light-emitting material.

Although not shown in the drawing, a plurality of gate lines and data lines may be disposed on the substrate 20 and may extend in directions intersecting each other to define the plurality of pixel areas P in a matrix manner. In this regard, the gate line and the data line may be connected to the light-emitting element 14, and ends of the gate line and the data line may be provided with a gate pad and a data pad connected to an external component, respectively. When an external signal is applied to the light-emitting element 14 through the gate line and the data line, the light-emitting element 14 operates and emits light.

A planarization layer PAC may be disposed between the light-emitting element 14R and the redundant light-emitting element 12R. The planarization layer PAC includes a first side and a second side that is opposite the first side. The connection electrode 300 may be disposed on the planarization layer PAC and may connect the first electrode PE1 of the light-emitting element 14R and the second electrode NE2 of the redundant light-emitting element 12R to each other. In one embodiment, the first electrode PE1 and the second electrode NE2 have opposite polarities from each other.

For example, the first electrode PE1 may be a P-type electrode and is at the first side of the planarization layer PAC, and the second electrode NE2 may be an N-type electrode and is at the second side of the planarization layer PAC. In one embodiment, the first electrode PE1 and the second electrode NE2 are on a same plane. The first electrode PE1 may be an electrode in contact with the P-type semiconductor layer in the light-emitting layer of the light-emitting element 14R, and may be composed of a single layer or a plurality of layers made of at least one of nickel (Ni), gold (Au), platinum (Pt), titanium (Ti), aluminum (Al), chromium (Cr), copper (Cu), or alloys thereof. The second electrode NE2 may be an electrode in contact with the N-type semiconductor layer in the light-emitting layer of the redundant light-emitting element 12R, and may be composed of a single layer or plurality of layers made of at least one of nickel (Ni), gold (Au), platinum (Pt), titanium (Ti), aluminum (Al), chromium (Cr), copper (Cu), or alloys thereof.

The light-emitting element 14R may include an anode electrode AE disposed on a thin-film transistor layer TAS at the first side of the planarization layer PAC. The second electrode NE1 of the light-emitting element 14R may be disposed on an upper surface of the anode electrode AE at the first side of the planarization layer PAC. A first light-emitting layer EL1 may be disposed on the second electrode NE1 of the light-emitting element 14R at the first side of the planarization layer PAC. The first electrode PE1 of the light-emitting element 14R may be disposed on the first light-emitting layer EL1. The anode electrode AE, the second electrode NE1, the first light-emitting layer EL1, and the first electrode PE1 may collectively form the light-emitting element 14R whereas the cathode electrode CE, the first electrode PE2, the second light-emitting layer EL2, and the second electrode NE2 may collectively form the redundant light-emitting element 12R.

The redundant light-emitting element 12R may include a cathode electrode CE disposed on the thin-film transistor layer TAS. The first electrode PE2 of the redundant light-emitting element 12R may be disposed on an upper surface of the cathode electrode CE. A second light-emitting layer EL2 may be disposed on the first electrode PE2 of the redundant light-emitting element 12R. The second electrode NE2 of the redundant light-emitting element 12R may be disposed on the second light-emitting layer EL2. Each of the first light-emitting layer EL1 and the second light-emitting layer EL2 may include a N-type semiconductor layer, an active layer and a P-type semiconductor layer.

The cathode electrode CE may be made of a metal material such as magnesium (Mg) or silver-magnesium (Ag:Mg) which is a conductive material. However, the present disclosure is not limited thereto. In another example, the cathode electrode CE may be made of transparent conductive oxide such as indium tin oxide (ITO), indium zinc oxide (IZO), indium tin zinc oxide Indium (ITZO), zinc oxide (ZnO) and tin oxide (TO).

Referring to FIG. 6, the connection electrode 300 connecting the first electrode PE1 of the light-emitting element 14R and the second electrode NE2 of the redundant light-emitting element 12R to each other may include copper (Cu).

Referring to FIG. 7, a connection electrode 400 may include a transparent conductive material. The connection electrode 400 connecting the first electrode PE1 of the light-emitting element 14R and the second electrode NE2 of the redundant light-emitting element 12R to each other may be made of indium tin oxide (ITO) or indium zinc oxide (IZO).

Each of the light-emitting element 14R and the redundant light-emitting element 12R may be embodied as a micro light-emitting diode.

Referring to FIG. 3, FIG. 6 and FIG. 7, the thin-film transistor layer TAS of the display device 100 according to one embodiment of the present disclosure may include the substrate 20, the buffer layer 205 disposed on the substrate 20, the light-blocking layer 210 disposed on the buffer layer, the first interlayer insulating layer 215 disposed on the light-blocking layer, the semiconductor layer 220 disposed on the first interlayer insulating layer, and the gate insulating layer 225 disposed on the semiconductor layer as previously described with respect to FIG. 3.

Further, the thin-film transistor layer TAS may further include the gate electrode 230 and the first interlayer connection electrode 231 disposed on the gate insulating layer 225, the second interlayer insulating layer 235 disposed on the gate electrode and the first interlayer connection electrode, and the connection line 240 disposed on the second interlayer insulating layer 235 as previously described with respect to FIG. 3.

Further, the thin-film transistor layer TAS may further include the third interlayer insulating layer 245 disposed on the second interlayer insulating layer 235 and the connection line 240, the source/drain electrodes 260 and the second interlayer connection electrode 261 disposed on the third interlayer insulating layer 245, and the first planarization layer 265 disposed on the third interlayer insulating layer 245, the source/drain electrode 260, and the second interlayer connection electrode 261. The anode electrode AE (i.e., the first connection electrode 274) of the light-emitting element 14R and the cathode electrode CE (i.e., the second connection electrode 280) of the redundant light-emitting element 12R are disposed on the first planarization layer 265.

The first interlayer connection electrode 231 may be connected to the light-blocking layer 210 via a first through-hole. The first through-hole is filled with the first interlayer connection portion 232. The first interlayer connection electrode 231 may be connected to the light-blocking layer 210 via the first interlayer connection portion 232. The source electrode 260 may be connected to the semiconductor layer 220 via a second through-hole and is connected to the connection line 240 via a third through-hole, and the drain electrode 260 is connected to the connection line 240 via fourth through-hole and is connected to the semiconductor layer 220 via a fifth through-hole.

The second interlayer connection electrode 261 may be connected to each of the connection line 240 via a sixth through-hole and is connected to the first interlayer connection electrode 231 via a seventh through-hole. The first connection electrode 274 (i.e., the anode electrode AE) may be connected to one of the source electrode or the drain electrode 260 via an eighth through-hole.

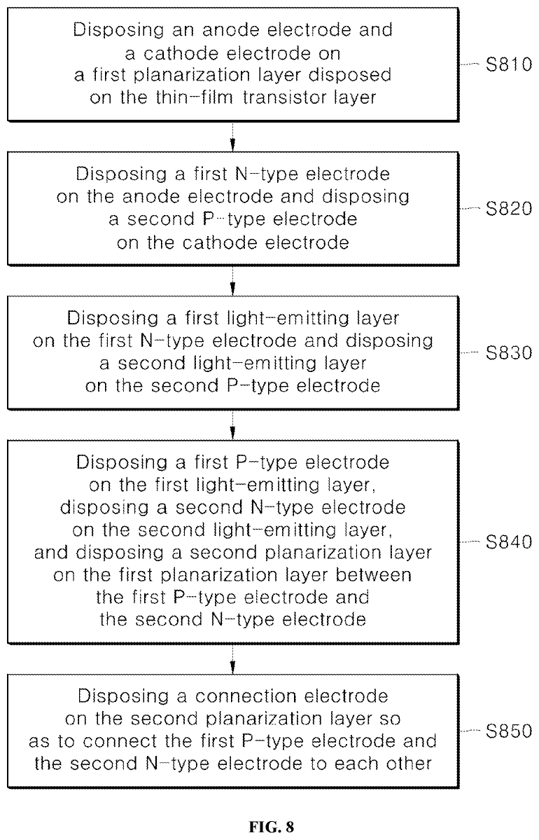

FIG. 8 is a flowchart illustrating a method for manufacturing a display device according to one embodiment of the present disclosure.

Referring to FIG. 8, in the method for manufacturing the display device 100 according to one embodiment of the present disclosure, the anode electrode AE and the cathode electrode CE may be disposed on the first planarization layer 265 of the thin film transistor layer TAS in step S810. The anode electrode AE may be the first connection electrode 274 in FIG. 3, and the cathode electrode CE may be the second connection electrode 280 in FIG. 3.

Subsequently, the first N-type electrode NE1 may be disposed on the anode electrode AE, and the second P-type electrode PE2 may be disposed on the cathode electrode CE in step S820. The first N-type electrode NE1 may be the first light-emitting electrode 140 in FIG. 3.

Subsequently, the first light-emitting layer EL1 may be disposed on the first N-type electrode NE1, and the second light-emitting layer EL2 may be disposed on the second P-type electrode PE2 in step S830.

Subsequently, the first P-type electrode PE1 (e.g., a first type) may be disposed on the first light-emitting layer EL1 to form the light-emitting element 14R, and the second N-type electrode NE2 (e.g., a second type) may be disposed on the second light-emitting layer EL2 to form the redundant light-emitting element 12R, in step S840. The second planarization layer (PAC) 283 may be disposed on the first planarization layer 265 and between the first P-type electrode PE1 and the second N-type electrode NE2 in setp S840. The first P-type electrode PE1 may be the second light-emitting electrode 145 in FIG. 3. The first N-type electrode NE1 may be an electrode in contact with a N-type semiconductor layer in the first light-emitting layer EL1, and the first P-type electrode PE1 may be an electrode in contact with a P-type semiconductor layer in the first light-emitting layer EL1. The second P-type electrode PE2 may be an electrode in contact with a P-type semiconductor layer in the second light-emitting layer EL2, and the second N-type electrode NE2 may be an electrode in contact with a N-type semiconductor layer in the second light-emitting layer EL2.

Subsequently, the connection electrode 300 or 400 connecting the first P-type electrode PE1 and the second N-type electrode NE2 may be disposed on the second planarization layer (PAC) 283 in step S850.

Therefore, even when the light-emitting element 14R is defective, the redundant light-emitting element 12R can performs a light-emitting operation, thereby lowering a failure of each pixel.

As described above, according to one embodiment of the present disclosure, the display device in which the redundant light-emitting element is applicable to the micro light-emitting display device to which a high-resolution panel is applied may be realized.

Further, according to one embodiment of the present disclosure, the method for manufacturing the display device in which the redundant light-emitting element is disposed in a manner corresponding to the main light-emitting element, and the electrodes having opposite polarities of the main light-emitting element and the redundant light-emitting element are connected to each other via the connection electrode may be realized.

Although the embodiments of the present disclosure have been described in more detail with reference to the accompanying drawings, the present disclosure is not necessarily limited to these embodiments, and may be modified in various manners within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments as described above are not restrictive but illustrative in all respects.

What is claimed is:

1. A display device comprising:
a light-emitting element including a first electrode of a first type, a second electrode of a second type that is different from the first type and disposed opposite the first electrode, and a first light emitting layer between the first electrode of the first type and the second electrode of the second type;
a redundant light-emitting element including a second electrode of the second type, a first electrode of the first type that is disposed opposite the second electrode of the second type of the redundant light-emitting element, and a second light emitting layer between the second electrode of the second type and the first electrode of the first type of the redundant light-emitting element; and
a connection electrode connected to the first electrode of the first type of the light-emitting element and the second electrode of the second type of the redundant light-emitting element.

2. The display device of claim 1, further comprising:
a planarization layer between the light-emitting element and the redundant light-emitting element,
wherein the connection electrode is on the planarization layer.

3. The display device of claim 1, wherein the first electrode of the first type of the light-emitting element and the first electrode of the first type of the redundant light-emitting element are P-type electrodes in contact with a P-type semiconductor layer in a light-emitting layer of the light-emitting element, and the second electrode of the second type of the light-emitting element and the second electrode of the second type of the redundant light-emitting element are N-type electrodes in contact with a N-type semiconductor layer in a light-emitting layer of the redundant light-emitting element.

4. The display device of claim 1, wherein the light-emitting element further comprises:
an anode electrode on a thin-film transistor layer,
wherein the second electrode of the second type of the light-emitting element is on the anode electrode.

5. The display device of claim 4, wherein the redundant light-emitting element further comprises:
a cathode electrode on the thin-film transistor layer;
wherein the first electrode of the first type of the redundant light-emitting element is on the cathode electrode.

6. The display device of claim 5, wherein each of a first light-emitting layer and a second light-emitting layer includes a N-type semiconductor layer, an active layer and a P-type semiconductor layer.

7. The display device of claim 1, wherein the connection electrode includes copper.

8. The display device of claim 1, wherein the connection electrode includes a transparent conductive material.

9. The display device of claim 8, wherein the transparent conductive material includes indium tin oxide or indium zinc oxide.

10. The display device of claim 1, wherein each of the light-emitting element and the redundant light-emitting element includes a micro light-emitting diode.

11. The display device of claim 5, wherein the thin-film transistor layer includes:
a substrate;
a buffer layer on the substrate;
a light-blocking layer on the buffer layer;
a first interlayer insulating layer on the light-blocking layer;
a semiconductor layer on the first interlayer insulating layer;
a gate insulating layer on the semiconductor layer;
a gate electrode and a first interlayer connection electrode on the gate insulating layer;
a second interlayer insulating layer on the gate electrode and the first interlayer connection electrode;
a connection line on the second interlayer insulating layer;
a third interlayer insulating layer on the second interlayer insulating layer and the connection line;
a source electrode, a drain electrode, and a second interlayer connection electrode on the third interlayer insulating layer; and
a first planarization layer on the third interlayer insulating layer, the source electrode, the drain electrode, and the second interlayer connection electrode;
wherein the anode electrode and the cathode electrode on the first planarization layer.

12. The display device of claim 11, wherein the first interlayer connection electrode is connected to the light-blocking layer via a first through-hole,
wherein the source electrode is connected to the semiconductor layer via a second through-hole and is connected to the connection line via a third through-hole, and the drain electrode is connected to the connection line via a fourth through-hole and is connected to the semiconductor layer via a fifth through-hole,
wherein the second interlayer connection electrode is connected to the connection line via a sixth through-hole and is connected to the first interlayer connection electrode via a seventh through-hole,
wherein the anode electrode is connected to one of the source electrode or the drain electrode via an eighth through-hole.

13. The display device of claim 1, wherein the first electrode of the light-emitting element and the second electrode of the redundant light-emitting element have opposite polarities.

14. The display device of claim 1, wherein the light-emitting element and the redundant light-emitting element corresponding thereto belong to a same sub-pixel and emit light of same color.

15. A display device comprising:
a planarization layer having a first side and a second side that is opposite the first side;
a first P-type electrode at the first side of the planarization layer;
a first N-type electrode at the first side of the planarization layer;
a first light emitting layer between the first P-type electrode and the first N-type electrode at the first side of the planarization layer;
a second N-type electrode at the second side of the planarization layer;
a second P-type electrode at the second side of the planarization layer;
a second light emitting layer between the second N-type electrode and the second P-type electrode; and
a connection electrode including a first end that is connected to the first P-type electrode at the first side of the planarization layer and a second end that is connected to the second N-type electrode at the second side of the planarization layer.

16. The display device of claim 15, wherein the first P-type electrode at the first side of the planarization layer and the second N-type electrode at the second side of the planarization layer are on a same plane.

17. The display device of claim 15, further comprising:
an anode electrode at the first side of the planarization layer;
a cathode electrode at the second side of the planarization layer,
wherein the first N-type electrode is on an upper surface of the anode electrode at the first side of the planarization layer and the second P-type electrode is on an upper surface of the cathode electrode at the second side of the planarization layer.

18. The display device of claim 15, wherein the connection electrode includes copper.

19. The display device of claim 15, wherein the connection electrode includes a transparent conductive material.

20. The display device of claim 17, wherein the anode electrode, the first P-type electrode, the first N-type electrode, and the first light emitting layer collectively form a light-emitting element, and the cathode electrode, the second N-type electrode, the second P-type electrode, and the second light emitting layer collective form a redundant light emitting element,
wherein the light-emitting element and the redundant light emitting element emit a same color of light.

21. The display device of claim 20, wherein the light-emitting element is a first micro light emitting diode chip and the redundant light emitting element is a second micro light emitting diode chip.

22. The display device of claim 21, further comprising:
a thin-film transistor layer including a thin-film transistor,
wherein the first micro light emitting diode chip and the second micro light emitting diode chip are on the thin-film transistor layer and the anode electrode of the first micro light emitting diode chip is connected to the thin-film transistor.
